(19) United States
(12) Patent Application Publication
(10) Pub. No.: US 2016/0079497 A1
(43) Pub. Date: Mar. 17, 2016

(54) SEMICONDUCTOR LIGHT EMITTING DEVICE AND LIGHT EMITTING APPARATUS

(71) Applicant: KABUSHIKI KAISHA TOSHIBA, Tokyo (JP)

(72) Inventors: Rintaro OKAMOTO, Nonoichi Ishikawa (JP); Shinji NUNOTANI, Kanazawa Ishikawa (JP)

(21) Appl. No.: 14/634,889

(22) Filed: Mar. 1, 2015

(30) Foreign Application Priority Data
Sep. 16, 2014 (JP) 2014-187332

(51) Int. Cl. H01L 33/60; H01L 33/54; H01L 33/00; H01L 33/62; H01L 33/50

(52) U.S. Cl. CPC H01L 33/60; H01L 33/62; H01L 33/507; H01L 33/0079; H01L 33/0075; H01L 33/54; H01L 33/0066; H01L 2933/0033; H01L 2933/0041; H01L 2933/0058; H01L 2933/005

(57) ABSTRACT

A semiconductor light emitting device is provided. The semiconductor light emitting device includes a semiconductor substrate having a first face on a first side, a second face on a second side opposite to the first face, and a third face which joins the first face and the second face. The semiconductor light emitting device further includes a first light reflection film in contact with at least a portion of the third face of the semiconductor substrate. The semiconductor device further includes a laminated body that is provided on the second side of the semiconductor substrate, and includes a first semiconductor layer, a second semiconductor layer, and a light emitting layer provided between the first semiconductor layer and the second semiconductor layer.

### CROSS-REFERENCE TO RELATED APPLICATION

This application is based upon and claims the benefit of priority from Japanese Patent Application No. 2014-187332, filed Sep. 16, 2014, the entire contents of which are incorporated herein by reference.

### FIELD

Embodiments described herein relate generally to a semiconductor light emitting device, and a light emitting apparatus.

### BACKGROUND

A light emitting apparatus including a semiconductor light emitting device, such as a light emitting diode (LED), can radiate mixed light by mixing the light which is emitted from a light emitting layer of the semiconductor light emitting device, and the light which is emitted from a fluorescent body. For example, a fluorescent material can be dispersed in a resin layer which is provided in the vicinity of the semiconductor light emitting device.

When the light emitted from the light emitting layer excites the fluorescent material dispersed in the resin layer, a portion of the light is reflected by a component of the fluorescent material and the resin layer. Hence, the light emitted from the light emitting layer becomes scattered within the resin layer. When the scattered light hits a substrate of the semiconductor light emitting device, the light may be absorbed into the substrate, and light intensity of the light emitting apparatus may be lowered, if the substrate is a semiconductor substrate.

### DESCRIPTION OF THE DRAWINGS

FIG. 1A is a schematic cross-sectional view illustrating a semiconductor light emitting device according to a first embodiment, and FIG. 1B is a schematic plan view illustrating the semiconductor light emitting device according to the first embodiment.

FIG. 2A to FIG. 2C are schematic cross-sectional views illustrating a manufacturing process of the semiconductor light emitting device according to the first embodiment.

FIG. 3A to FIG. 3C are schematic cross-sectional views illustrating the manufacturing process of the semiconductor light emitting device according to the first embodiment.

FIG. 4 is a schematic cross-sectional view illustrating a light emitting apparatus according to the first embodiment.

FIG. 5 is a schematic cross-sectional view illustrating a light emitting apparatus according to a second embodiment.

FIG. 6A is a schematic cross-sectional view illustrating a semiconductor light emitting device according to a third embodiment, and FIG. 6B is a perspective schematic diagram of the semiconductor light emitting device according to the third embodiment, and a substrate on which the semiconductor light emitting device is mounted.

### DETAILED DESCRIPTION

An example embodiment provides a semiconductor light emitting device and a light emitting apparatus having high light emitting intensity.

In general, according to one embodiment, a semiconductor light emitting device includes a semiconductor substrate having a first face on a first side, a second face on a second side opposite to the first face, and a third face which joins the first face and the second face. The semiconductor light emitting device further includes a first light reflection film in contact with at least a portion of the third face of the semiconductor substrate. The semiconductor device further includes a laminated body that is provided on the second side of the semiconductor substrate, and includes a first semiconductor layer, a second semiconductor layer, and a light emitting layer provided between the first semiconductor layer and the second semiconductor layer.

Hereinafter, example embodiments will be described with reference to the drawings. In the following description, the same reference numerals are given to the same or substantially same elements or aspects depicted in different drawings, as such the description of repeated elements or aspects having been described once in conjunction with a drawing, may be appropriately omitted in discussion related to a subsequent drawing.

### First Embodiment

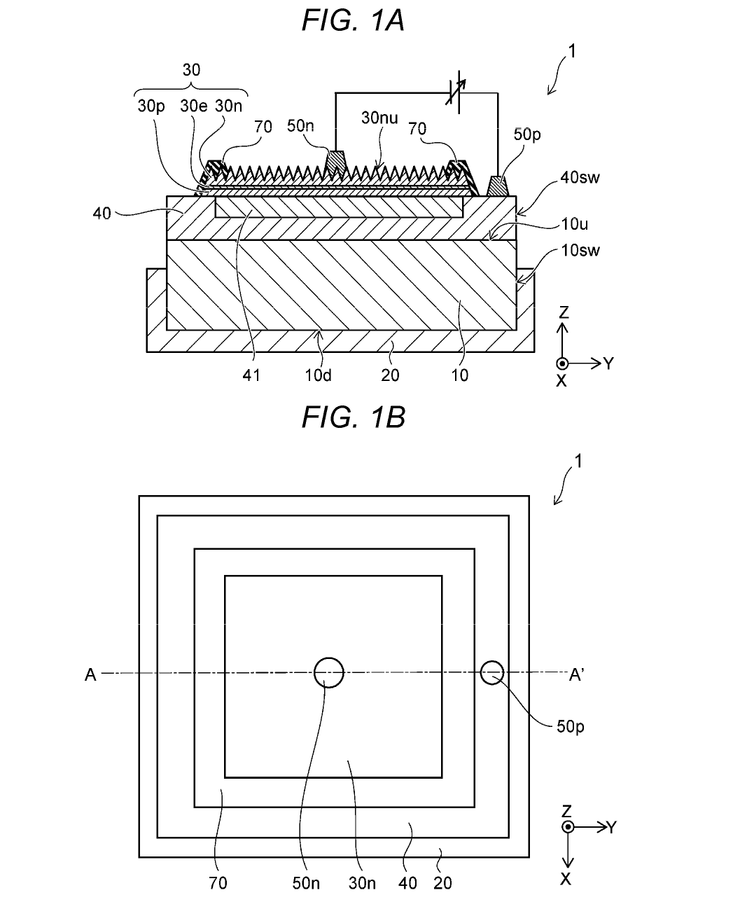

FIG. 1A is a schematic cross-sectional view illustrating a semiconductor light emitting device according to a first embodiment, and FIG. 1B is a schematic plan view illustrating the semiconductor light emitting device according to the first embodiment.

FIG. 1A shows a cross section taken along an A-A′ line of FIG. 1B. Moreover, in the drawings which are shown hereinafter, three-dimensional coordinates are introduced for purposes of explanation.

A semiconductor light emitting device 1 according to the first embodiment, includes a semiconductor substrate 10, a first light reflection film (hereinafter, for example, light reflection film 20), a laminated body 30, and a metal-containing film 40.

The semiconductor substrate 10 includes a first face (hereinafter, for example, lower face 10d), a second face (hereinafter, for example, upper face 10u) on an opposite side to the lower face 10d, and a third face (hereinafter, for example, side face 10sw) which joins the lower face 10d and the upper face 10u. For example, a thickness of the semiconductor substrate 10 between the lower face 10d and the upper face 10u is between about 100 μm to about 300 μm. The semiconductor substrate 10 includes silicon (Si), for example. For example, the semiconductor substrate 10 is a silicon substrate which is individualized (diced) from a silicon wafer.

The light reflection film 20 comes into contact with the lower face 10d of the semiconductor substrate 10, and at least a portion of the side face 10sw of the semiconductor substrate 10. In some embodiments, the light reflection film 20 may come into contact with the whole surface of the side face 10sw of the semiconductor substrate 10. Furthermore, the light reflection film 20 may come into contact with at least a portion of a side face 40sw of the metal-containing film 40.

The light reflection film 20 includes at least one element which is selected from a group comprising gold (Au), silver (Ag), aluminum (Al), zinc (Zn), zirconium (Zr), silicon (Si), germanium (Ge), platinum (Pt), rhodium (Rh), nickel (Ni), palladium (Pd), copper (Cu), tin (Sn), carbon (C), magnesium (Mg), chrome (Cr), tellurium (Te), selenium (Se), titanium (Ti), oxygen (O), hydrogen (H), tungsten (W), molybdenum (Mo), and a ceramic.

The light reflection film 20 may be a structure of multiple layers in which each layer of the multiple layer structure includes at least one element which is selected from the group comprising gold (Au), silver (Ag), aluminum (Al), zinc (Zn), zirconium (Zr), silicon (Si), germanium (Ge), platinum (Pt), rhodium (Rh), nickel (Ni), palladium (Pd), copper (Cu), tin (Sn), carbon (C), magnesium (Mg), chrome (Cr), tellurium (Te), selenium (Se), titanium (Ti), oxygen (O), hydrogen (H), tungsten (W), molybdenum (Mo), and a ceramic.

In order to improve a heat resistance property and a chemical resistance property of the light reflection film 20, an alloy including at least two of the group of the above metals, may be used as a material of the light reflection film 20.

The laminated body 30 is provided on the upper face 10u side of the semiconductor substrate 10. The laminated body 30 includes a first semiconductor layer (hereinafter, for example, semiconductor layer 30p), a second semiconductor layer (hereinafter, for example, semiconductor layer 30n), and a light emitting layer (active layer) 30e. The semiconductor layer 30p is a p-side clad layer, and the semiconductor layer 30n is an n-side clad layer.

The semiconductor layer 30p, the light emitting layer 30e, and the semiconductor layer 30n are aligned in a direction (Z direction of FIG. 1A) toward the upper face 10u from the lower face 10d of the semiconductor substrate 10. The light emitting layer 30e is provided between the semiconductor layer 30p and the semiconductor layer 30n.

The semiconductor layer 30p includes a nitride semiconductor. For example, the semiconductor layer 30p may include magnesium (Mg) as dopant. The semiconductor layer 30n includes a nitride semiconductor. For example, the semiconductor layer 30n may include silicon (Si) as dopant. The light emitting layer 30e includes a nitride semiconductor. For example, the light emitting layer 30e may have a single quantum well (SQW) structure, or may have a multi quantum well (MQW) structure.

Moreover, an upper face 30nu of the semiconductor layer 30n is concave and convex (roughened), in order to increase an extraction effect of the light which is radiated from the light emitting layer 30e.

The metal-containing film 40 is provided between the laminated body 30 and the semiconductor substrate 10. The laminated body 30 and the semiconductor substrate 10 are bonded by the metal-containing film 40, and thereby, the semiconductor light emitting device 1 is formed. The metal-containing film 40 includes a metal or a metallic compound.

Between the laminated body 30 and the metal-containing film 40, a second light reflection film (hereinafter, for example, light reflection film 41) is provided.

The light reflection film 41 includes at least one element which is selected from the group comprising gold (Au), silver (Ag), aluminum (Al), zinc (Zn), zirconium (Zr), silicon (Si), germanium (Ge), platinum (Pt), rhodium (Rh), nickel (Ni), palladium (Pd), copper (Cu), tin (Sn), carbon (C), magnesium (Mg), chrome (Cr), tellurium (Te), selenium (Se), titanium (Ti), oxygen (O), hydrogen (H), tungsten (W), and molybdenum (Mo).

The light reflection film 41 may be a multiple layer structure in which each layer of the multiple layer structure includes at least one element which is selected from the group of gold (Au), silver (Ag), aluminum (Al), zinc (Zn), zirconium (Zr), silicon (Si), germanium (Ge), platinum (Pt), rhodium (Rh), nickel (Ni), palladium (Pd), copper (Cu), tin (Sn), carbon (C), magnesium (Mg), chrome (Cr), tellurium (Te), selenium (Se), titanium (Ti), oxygen (O), hydrogen (H), tungsten (W), and molybdenum (Mo).

In order to improve the heat resistance property and the chemical resistance property of the light reflection film 41, an alloy including at least two of the group of the above metals, may be used as a material of the light reflection film 41.

To the semiconductor layer 30n, an n-side electrode 50n is connected. When the semiconductor light emitting device 1 is seen from the Z direction, the electrode 50n is positioned substantially at a center of the semiconductor light emitting device 1. Additionally, a p-side electrode 50p is connected to the metal-containing film 40.

For example, the electrode 50p and the electrode 50n include at least one metal which is selected from the group of aluminum (Al), titanium (Ti), nickel (Ni), tungsten (W), gold (Au), and the like.

Moreover, a protective film 70 is provided on a side section of the laminated body 30, and from the side section of the laminated body 30 to a portion on the inside of the laminated body 30.

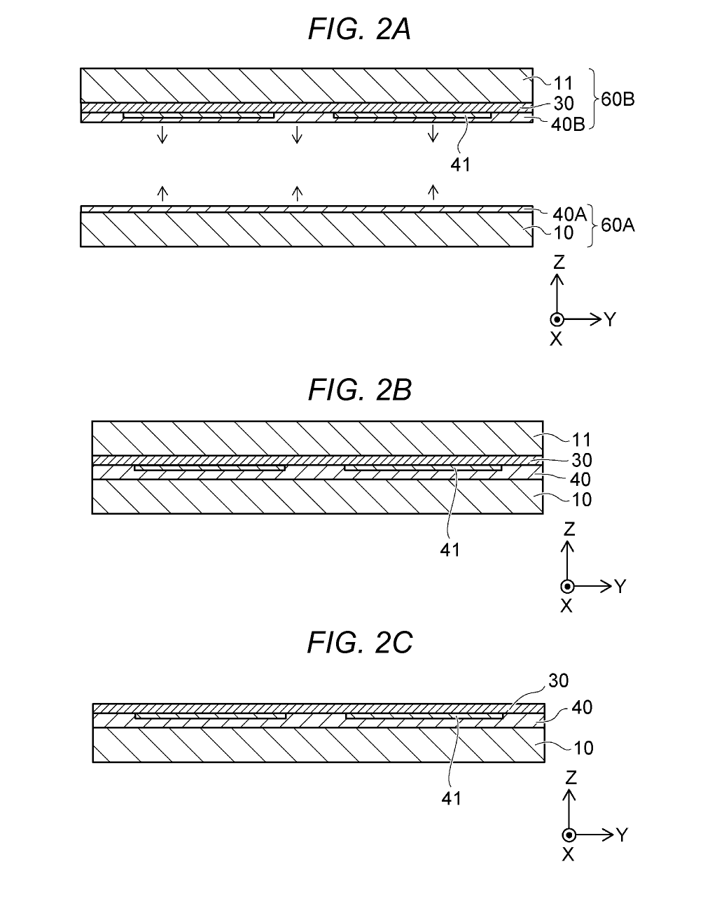

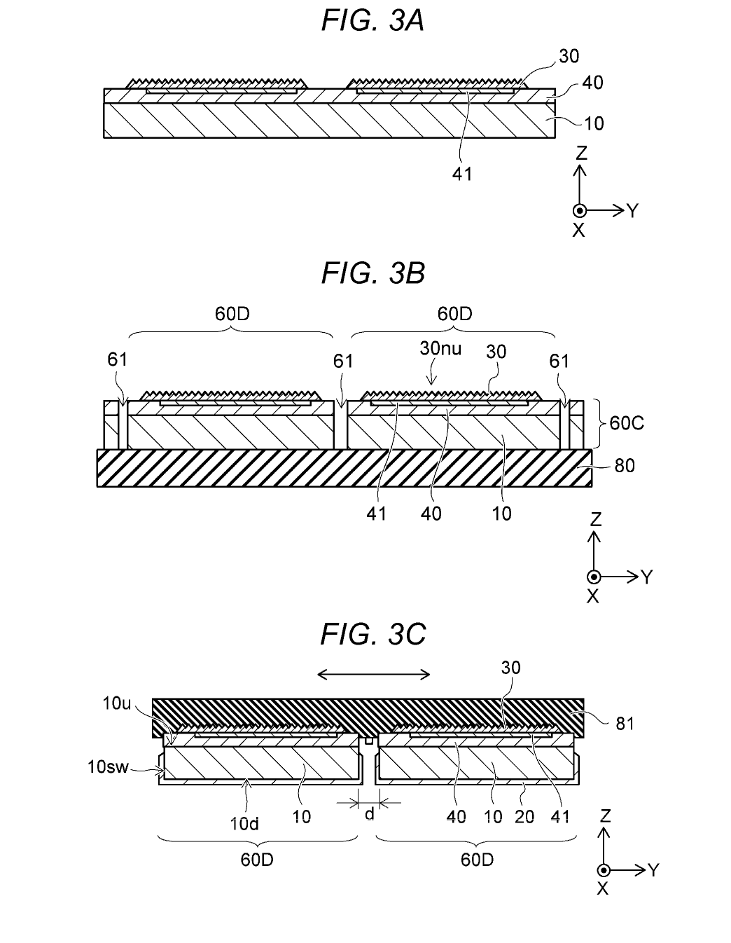

FIG. 2A to FIG. 3C are schematic cross-sectional views illustrating a manufacturing process of the semiconductor light emitting device according to the first embodiment.

As shown in FIG. 2A, a structured body 60A, and a structured body 60B are opposed to each other. In the structured body 60A, a metal-containing film 40A is provided on the semiconductor substrate 10. In the structured body 60B, the laminated body 30 is provided under a semiconductor substrate 11, the light reflection film 41 is selectively provided under the laminated body 30, and a metal-containing film 40B is provided under the laminated body 30 and the light reflection film 41. The semiconductor substrate 11 is a silicon substrate, a sapphire substrate, or the like.

Next, as illustrated in FIG. 2B, the metal-containing film 40A and the metal-containing film 40B are caused to come into contact with each other, and thereby, the metal-containing film 40 is formed between the semiconductor substrate 10 and the laminated body 30, and between the semiconductor substrate 10 and the light reflection film 41. That is, the semiconductor substrate 10 and the laminated body 30 are bonded by the metal-containing film 40, and the semiconductor substrate 10 and the light reflection film 41 are bonded by the metal-containing film 40.

Subsequently, as illustrated in FIG. 2C, the semiconductor substrate 11 is removed (e.g., peeled off) from the laminated body 30.

Next, as illustrated in FIG. 3A, the laminated body 30 which is provided on the metal-containing film 40 and the light reflection film 41, is divided by, for example, dry etching. Additionally, the upper face 30nu of the semiconductor layer 30n, which is included in the laminated body 30, is processed to have a concave and convex shape (a roughened interfacial surface).

Subsequently, as illustrated in FIG. 3B, a structured body 60C including the semiconductor substrate 10, the metal-containing film 40, the light reflection film 41, and the laminated body 30, is mounted on a dicing sheet 80. Here, the semiconductor substrate 10 comes into contact with the dicing sheet 80.

Thereafter, a portion of the metal-containing film 40, which is positioned between the adjacent laminated bodies 30, and a portion of the semiconductor substrate 10 under the same, are removed by dicing. By the dicing, a trench 61 is formed in the structured body 60C. That is, the structured body 60C is individualized into a plurality of structured bodies 60D.

Next, as illustrated in FIG. 3C, a resin sheet 81 is prepared. The resin sheet 81 is flexible and has elasticity. Thereafter, the structured body 60D on the laminated body 30 side is pressed onto the resin sheet 81. Furthermore, the resin sheet 81 is expanded along a sheet face of the resin sheet 81 as indicated by the bidirectional arrow, and a gap d between the adjacent structured bodies 60D is adjusted.

Subsequently, the light reflection film 20 is formed by, for example, a sputtering method, on the lower face 10d of the semiconductor substrate 10 of the structured body 60D, and at least a portion of the side face 10sw. In the sputtering, the light reflection film 20 is formed on the lower face 10d of the semiconductor substrate 10, and in addition thereto, the light reflection film 20 is extended up to cover at least portions of one or more of the side face 10sw of the semiconductor substrate 10. Here, the gap d and/or a sputtering condition can be appropriately adjusted so that the light reflection film 20 is formed on the lower face 10d of the semiconductor substrate 10, and at least a portion of the side face 10sw.

Thereafter, the electrodes 50p and 50n, the protective film 70, and the like are formed on the structured body 60D, and thereby, the semiconductor light emitting device 1 is formed.

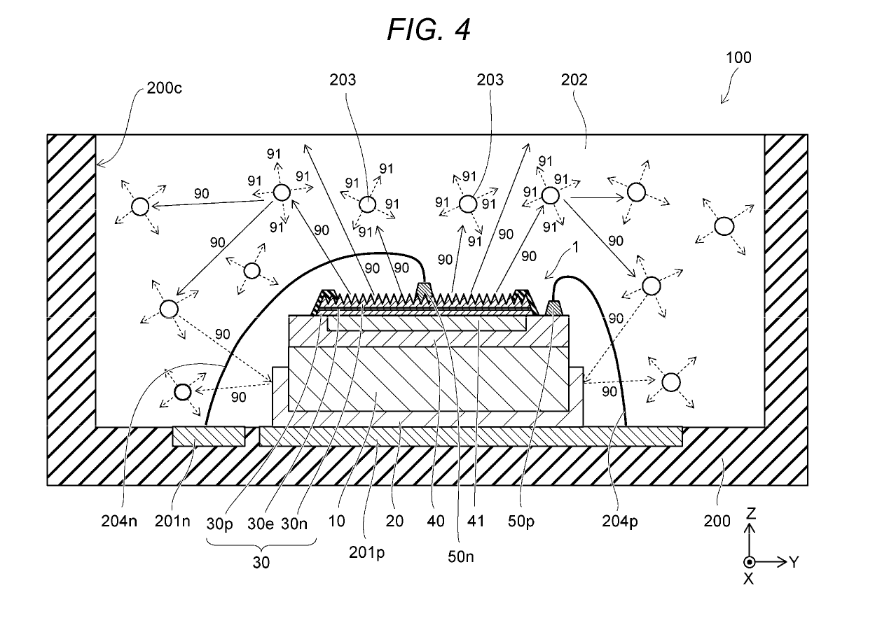

FIG. 4 is a schematic cross-sectional view illustrating a light emitting apparatus according to the first embodiment.

A light emitting apparatus 100 includes a container 200, a substrate 201p, a substrate 201n, the semiconductor light emitting device 1, a resin layer 202, the fluorescent bodies 203, a wire 204p, and a wire 204n. The semiconductor light emitting device which is included in the light emitting apparatus 100, is not limited to the semiconductor light emitting device 1 according to the first embodiment, and may be a semiconductor light emitting device such as that is described later, for example.

The container 200 is a resin container of which an upper side is open. The container 200 has a concave section 200c. The substrate 201p and the substrate 201n are provided in the concave section 200c. The semiconductor light emitting device 1 is provided on the substrate 201p. For example, the substrate 201p and the substrate 201n include a low resistance material, such as a metal, such as copper (Cu). Substrate 201n and substrate 201p, may, for example, be portions of a lead frame element.

The semiconductor light emitting device 1 is provided in the concave section 200c of the container 200. For example, the light reflection film 20 of the semiconductor light emitting device 1 is connected to the substrate 201p by solder, silver paste, or the like.

The electrode 50p of the semiconductor light emitting device 1 is electrically connected to the substrate 201p through the wire 204p. In other words, the potential which is applied to the substrate 201p from the outside of the light emitting apparatus 100, is conducted to the electrode 50p of the semiconductor light emitting device 1 through the wire 204p. Here, the electrode 50p is connected to the p-side semiconductor layer 30p of the semiconductor light emitting device 1. That is, the potential which is applied to the substrate 201p is conducted to the p-side semiconductor layer 30p.

The electrode 50n of the semiconductor light emitting device 1 is electrically connected to the substrate 201n through the wire 204n. In other words, the potential which is applied to the substrate 201n from the outside of the light emitting apparatus 100, is conducted to the electrode 50n of the semiconductor light emitting device 1 through the wire 204n. Here, the electrode 50n is connected to the n-side semiconductor layer 30n of the semiconductor light emitting device 1. That is, the potential which is applied to the substrate 201n is conducted to the n-side semiconductor layer 30n.

The resin layer 202 is provided on the substrate 201p, the substrate 201n, and the semiconductor light emitting device 1. The resin layer 202 is provided in the concave section 200c of the container 200. The resin layer 202 includes the fluorescent bodies 203. The fluorescent bodies 203 are dispersed in the resin layer 202. A filler may also be dispersed in the resin layer 202.

Next, an operation of the light emitting apparatus 100 will be described.

If a potential which is higher than the potential at the n-side electrode 50n, is applied to the p-side electrode 50p, a forward bias is applied to the p-side semiconductor layer 30p and the n-side semiconductor layer 30n. Hereby, a positive hole and an electron are recombined within the light emitting layer 30e of the semiconductor light emitting device 1. If the positive hole and the electron are recombined within the light emitting layer 30e, the light emitting layer 30e radiates a blue light 90, for example, wavelength: 450 nm.

The blue light 90 is a primary light of the light emitting apparatus 100. The blue light 90, which is radiated to the upper side from the light emitting layer 30e, is radiated to the upper side of the semiconductor light emitting device 1 by passing through the semiconductor layer 30n. The blue light 90 which is radiated to a lower side from the light emitting layer 30e, is reflected by the light reflection film 41 after passing through the semiconductor layer 30p, and is reflected to the upper side of the semiconductor light emitting device 1.

If the blue light 90 is incident on a fluorescent body 203, the fluorescent body 203 absorbs the blue light 90, and for example, emits a yellow light 91. The yellow light 91 is a secondary light of the light emitting apparatus 100. From the light emitting apparatus 100, a substantially white light can be emitted by color mixing of the blue light 90 of the primary light and the yellow light 91 of the secondary light.

Here, the blue light 90, which is emitted from the semiconductor light emitting device 1, is absorbed by the fluorescent bodies 203, and is also scattered by the fluorescent bodies 203 and/or the filler. Moreover, there is a case when the blue light 90 can be reflected by an inner wall of the container 200, or an interface between the resin layer 202 and the atmosphere, and the light traverses the resin layer 202 again after reflection.

If the scattered light or the reflected blue light 90 falls on one of the fluorescent bodies 203, the fluorescent body 203 radiates more yellow light 91, and light intensity of the yellow light of the secondary light, becomes relatively high. Hereby, light emitting intensity of the light emitting apparatus 100 becomes high.

If the light reflection film 20 were to be removed from the semiconductor light emitting device 1, the semiconductor substrate 10 would be exposed to the resin layer 202. If the semiconductor substrate 10 is exposed to the resin layer 202, the scattered light or the reflected light of the blue light traveling through the resin layer 202 can directly fall on the semiconductor substrate 10. Accordingly, a portion of the blue light, which is emitted from the semiconductor light emitting device 1, would be absorbed into the semiconductor substrate 10.

Hereby, the light intensity of the blue light 90 which is emitted from the semiconductor light emitting device 1 would become relatively low, and the light intensity of the yellow light 91 which is radiated from the fluorescent body 203 also becomes lower because the light intensity of the blue light 90 of the primary light is lower. In other words, in the light emitting apparatus from which the light reflection film 20 is removed, the light emitting intensity of the semiconductor light emitting device 1 is not obtained, and the light intensity becomes weaker in comparison.

In contrast, in the semiconductor light emitting device 1, the light reflection film 20 comes into contact with at least a portion of the side face 10sw of the semiconductor substrate 10. Hence, the scattered light or the reflected light of the blue light traveling through the resin layer 202 does not directly hit the semiconductor substrate 10 covered with the light reflection film 20. Accordingly, the semiconductor substrate 10 is less likely to absorb the scattered light or the reflected light of the blue light and consequently reduce emitted light intensity.

Furthermore, in the semiconductor light emitting device 1, the blue light 90 which is reflected by the light reflection film 20, falls on the fluorescent body 203 again. Hereby, the fluorescent body 203 absorbs the blue light 90, and the fluorescent body 203 emits the yellow light 91. The yellow light 91 contributes to an increase in the light intensity of the light emitting apparatus 100.

### Second Embodiment

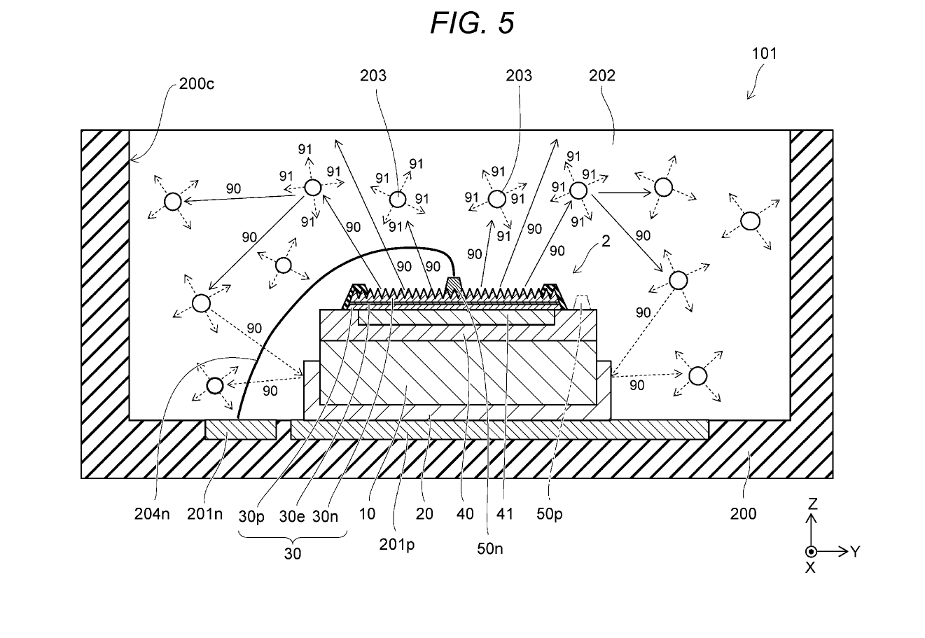

FIG. 5 is a schematic cross-sectional view illustrating a light emitting apparatus according to a second embodiment.

A light emitting apparatus 101, according to the second embodiment, includes a semiconductor light emitting device 2.

The electrode 50n of the semiconductor light emitting device 2 is electrically connected to the substrate 201n through the wire 204n. In other words, the potential which is applied to the substrate 201n from the outside of the light emitting apparatus 101, is conducted to the electrode 50n of the semiconductor light emitting device 2 through the wire 204n. That is, the potential which is applied to the substrate 201n is conducted to the n-side semiconductor layer 30n of the semiconductor light emitting device 2 through the electrode 50n.

Moreover, conductivity of the semiconductor substrate 10 of the semiconductor light emitting device 2 is set to be higher than the conductivity of the semiconductor substrate 10 of the semiconductor light emitting device 1. Here, the light reflection film 20 serves as a p-side electrode in addition to as a light reflection film. Accordingly, the potential which is applied to the substrate 201p from the outside of the light emitting apparatus 101, is conducted to the p-side semiconductor layer 30p of the semiconductor light emitting device 2 through the light reflection film 20, the metal-containing film 40, and the light reflection film 41.

In other words, in the semiconductor light emitting device 2, by applying the potential which is higher than that of the substrate 201n to the substrate 201p, a current flows between the electrode 50n and the light reflection film 20 which is positioned on the lower side of the electrode 50n.

Hereby, the current flowing to the n-side semiconductor layer 30n from the p-side semiconductor layer 30p is more uniformly dispersed in comparison with the semiconductor light emitting device 1. Accordingly, the light intensity of the semiconductor light emitting device 2 is expected to increase in comparison with the light intensity of the semiconductor light emitting device 1. In other words, the light intensity of the light emitting apparatus 101 increases in comparison with the light intensity of the light emitting apparatus 100.

In the second embodiment, it is preferable that the light reflection film 20 is connected to a portion of the side face 10sw of the semiconductor substrate 10, and does not come into contact with the side face 40sw of the metal-containing film 40 causing current flow through the semiconductor substrate 10. Hereby, a flow speed of the current in the Z direction increases, and the current flowing to the n-side semiconductor layer 30n from the p-side semiconductor layer 30p, is more uniformly dispersed.

In the second embodiment, since the light reflection film 20 is used as a p-side electrode, the p-side electrode 50p is not necessary. Accordingly, degrees of freedom in device design increase. Furthermore, the electrode 50p is not necessarily removed from the semiconductor light emitting device 2, and may therefore be used as a terminal for inspection or testing. That is, the electrode 50p may still optionally be present in the second embodiment, even though it is not bonded via wire 204p to substrate 201p.

### Third Embodiment

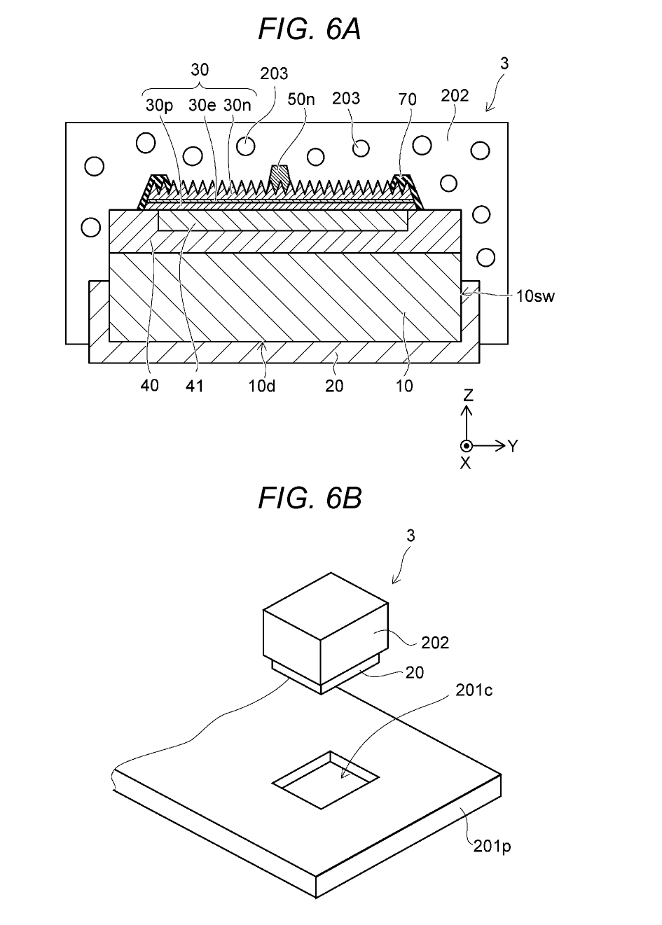

FIG. 6A is a schematic cross-sectional view illustrating a semiconductor light emitting device according to a third embodiment, and FIG. 6B is a perspective schematic diagram of the semiconductor light emitting device according to the third embodiment, and a substrate on which the semiconductor light emitting device is mounted.

A semiconductor light emitting device 3 according to the third embodiment includes the semiconductor substrate 10, the light reflection film 20, the laminated body 30, the metal-containing film 40, the resin layer 202, and the fluorescent bodies 203. In the semiconductor light emitting device 3, the current flows between the electrode 50n and the light reflection film 20.

The resin layer 202 comes into contact with the light reflection film 20, the semiconductor substrate 10, the metal-containing film 40, and the laminated body 30. In other words, the light reflection film 20, the semiconductor substrate 10, the metal-containing film 40, and the laminated body 30 are sealed by the resin layer 202. Additionally, the light reflection film 20 which comes into contact with the lower face 10d of the semiconductor substrate 10 and a portion of the light reflection film 20 which comes into contact with the side face 10sw of the semiconductor substrate 10 are exposed from the resin layer 202. That is, the light reflection film 20 may extend beyond an outer surface of the resin layer 202 along the Z direction (as depicted in FIG. 6A) so as to provide a surface for electrical connections such as depicted in FIG. 6B.

In the semiconductor light emitting device 3, the light reflection film 20 comes into contact with at least a portion of the side face 10sw of the semiconductor substrate 10. Hence, the scattered light or the reflected light of the blue light does not directly fall on the semiconductor substrate 10. Accordingly, the semiconductor substrate 10 is less likely to absorb the scattered light or the reflected light of the blue light. In other words, the semiconductor light emitting device 3 provides the same or substantially similar effects as the semiconductor light emitting device 1.

Moreover, in FIG. 6B, the semiconductor light emitting device 3, and the substrate 201p where a concave section 201c is provided, are shown. The semiconductor light emitting device 3 may be inserted or installed in the concave section 201c, and thereby, the light reflection film 20 of the semiconductor light emitting device 3, and the concave section 201c of the substrate 201p are fitted to each other and thereby connected. In the semiconductor light emitting device 3, the container 200 is not necessary. Hence, miniaturization of the light emitting apparatus can be realized.

Additionally, in the embodiments, a structure in which the n-type semiconductor layer 30n is provided on the lower side of the light emitting layer 30e, and the p-type semiconductor layer 30p is provided on the upper side of the light emitting layer 30e, can also be included.

Moreover, planar shapes of the semiconductor substrate 10 and the laminated body 30 are not limited to rectangular shapes, and may be round shapes, for example.

In addition, in the embodiments, a term of “laminated” includes a case in which another layer (or layers) is disposed between two “laminated” layers or two layers “laminated” to each other. In addition, “laminated” includes a case of layers being in direct contact with each other. Still more, the term of “provided on” includes a case in which one or more layers (e.g., layer C, layer D) is disposed between a layer A “provided on” layer B, for example, in addition to a case of layer A being in direct contact with layer B.

Moreover, in the embodiments, the term of “nitride semiconductor” is assumed to include the semiconductors having all composition which are obtained from changing composition ratios of x, y, and z within each scope thereof in a chemical formula of BₓIn_{y}Al_{z}Ga_{1-x-y-z}N (0≦x≦1, 0≦y≦1, 0≦z≦1, and x+y+z≦1). Furthermore, in the above chemical formula, the composition further containing a V group element other than N (nitrogen), the composition further containing various elements which are added in order to control various physical properties such as a conductivity type, and the composition further containing various elements which are unintentionally included, are assumed to be included in the term of “nitride semiconductor”.

The example embodiments are described with reference to specific examples. However, the disclosure is not limited to the specific examples. That is, an example which is obtained from appropriately adding a design change to the specific examples by those skilled in the art is also included in the scope of the embodiments as long as characteristics of the embodiments are included. Each component which is included in each specific example described above, and a disposition thereof, a material thereof, a condition thereof, a shape thereof, size thereof, and the like are not limited to the examples, and may be appropriately changed.

Moreover, each of the components which are included in the embodiments described above may be combined as far as technically possible. The combinations are included in the scope of the embodiments as long as the characteristics of the embodiments are included. In addition, for those skilled in the art, without departing from the gist of the embodiments, various modification examples and alteration examples may be conceived, and it is understood that the modification examples and the alteration examples belong to the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor light emitting device, comprising:
a semiconductor substrate having a first face on a first side, a second face on a second side opposite to the first side, and a third face which connects the first face to the second face;
a first light reflection film on at least a portion of the third face of the semiconductor substrate; and
a laminated body on the second side of the semiconductor substrate, the laminated body including a first semiconductor layer, a second semiconductor layer, and a light emitting layer between the first and second semiconductor layers.

2. The semiconductor light emitting device according to claim 1, wherein the first light reflection film completely covers the third face.

3. The semiconductor light emitting device according to claim 1, further comprising:
a metal-containing film provided between the laminated body and the semiconductor substrate; and
a second light reflection film provided between the laminated body and the metal-containing film.

4. The semiconductor light emitting device according to claim 1, further comprising:
a resin layer in contact with the first light reflection film, the semiconductor substrate, and the laminated body.

5. The semiconductor light emitting device according to claim 4, wherein
a first portion of the first light reflection film covers the second face;
the resin layer surrounds a second portion the first light reflection film in a plane parallel to the second surface, and
the first portion of the first light reflection film is not in contact with the resin layer.

6. The semiconductor light emitting device according to claim 4, wherein the resin layer includes a plurality of fluorescent bodies.

7. The semiconductor light emitting device according to claim 1, wherein the first light reflecting film is selected from a group consisting of gold (Au), silver (Ag), or aluminum (Al).

8. The semiconductor light emitting device according to claim 1, wherein the semiconductor substrate comprises silicon.

9. The semiconductor light emitting device according to claim 1, further comprising:
a container including a concave section, the semiconductor substrate being within the concave section of the container;
the first light reflection film contacting a portion of the container within the concave section; and
a resin layer filling the concave section.

10. The semiconductor light emitting device according to claim 9, wherein the resin layer includes a plurality of fluorescent bodies dispersed therein.

11. The semiconductor light emitting device according to claim 9, wherein a first bonding wire electrically connects a first conductive portion of the container to the first semiconductor layer.

12. The semiconductor light emitting device according to claim 11, wherein a second bonding wire electrically connects a second conductive portion of the container to the second semiconductor layer.

13. The semiconductor light emitting device according to claim 11, wherein the first light reflection layer electrically connects a second conductive portion of the container to the second semiconductor layer.

14. The semiconductor light emitting device according to claim 9, wherein the first light reflection film completely covers the third face.

15. The semiconductor light emitting device according to claim 9, wherein the first light reflection film only partially covers the third face.

16. A semiconductor light emitting device, comprising:
a semiconductor substrate having a first face on a first side, a second face on a second side opposite to the first side, and a third face connecting the first face to the second face;
a first light reflection film on the first face and at least a first portion of third face; and
a laminated body disposed on the second side of the semiconductor substrate, the laminated body including a first semiconductor layer, a second semiconductor layer, and a light emitting layer between the first semiconductor layer and the second semiconductor layer.

17. The semiconductor light emitting device according to claim 16, wherein the first light reflection film completely covers the third face.

18. The semiconductor light emitting device according to claim 16, further comprising:
a resin layer including a plurality of fluorescent bodies, the resin layer disposed on the laminated body and surrounding at least a portion of the semiconductor substrate in a plane parallel to the second face.

19. A method, comprising:
forming a laminated body on a first substrate, the laminated body including a first semiconductor layer, a second semiconductor layer, and a light emitting layer between the first and second semiconductor layers;
bonding the laminated body to a second substrate having a first face on a first side, a second face on a second side opposite to the first side, the laminated body being on the second side of the second substrate;
removing at least a portion of the first substrate;
dicing the second substrate into a plurality of portions while the second substrate is supported on a dicing sheet, the dicing forming a third face on each of the plurality of portions of the second substrate, the third faces respectively connecting first and second faces of each of the plurality of portions of the second substrate;
adhering a resin sheet to the laminated body after dicing the second substrate; and
exposing the first face of the second substrate and then depositing a first light reflection film on the first face and at least a portion of at least one third face, wherein
a spacing between adjacent third faces during the depositing of the first light reflection film is adjusted by applying force to the resin sheet in a plane parallel to the first face.

20. The method of claim 19, wherein the first light reflection film completely covers the at least one third face.
